(19) United States
(12) Patent Application Publication
(10) Pub. No.: US 2006/0152270 A1
(43) Pub. Date: Jul. 13, 2006

(54) Circuit arrangement for electrically isolated signal transmission

(76) Inventor: Martin Buerkert, Doerzbach-Hohebach (DE)

Correspondence Address: BRINKS HOFER GILSON & LIONE, P.O. BOX 10395, CHICAGO, IL, 60610, US

(21) Appl. No.: 10/529,173

(22) PCT Filed: Jul. 24, 2003
(86) PCT No.: PCT/EP03/08131

§ 371 Date: Dec. 23, 2005

(30) Foreign Application Priority Data
Sep. 24, 2002 (DE) 102 44 665.2

(51) Int. Cl. H03L 5/00

(52) U.S. Cl. 327/333

(57) ABSTRACT

The invention relates to a circuit arrangement for DC-isolated transmission of an analog input variable by means of a signal transformation part, having a voltage input and a voltage output, and in particular also for voltage matching between the voltage input and the voltage output of the circuit arrangement. The signal transformation part is designed as an inductive signal transformation part (6) and the circuit arrangement is provided with a charging and discharging arrangement having a switching element (S1) in such a way that, as a result of the switching element (S1) being actuated, a charging or discharging current (i1, i2) that is proportional to an input voltage (U1) and flows through the signal transformation part (6) occurs and an output voltage (U3) is established at the voltage output.

The invention relates to a circuit arrangement for DC-isolated transmission of an analog input variable by means of a signal transformation part, having a voltage input and a voltage output, and in particular also for voltage matching between the voltage input and the voltage output of the circuit arrangement.

Circuit arrangements of this type are used in industry for the transmission of control signals in devices having an analog signal control input for 0 to 10 volts. Circuit arrangements of this type are also used for example for desired value setting of a regulator or for evaluation of a process variable in a control loop.

Owing to existing safety standards, a control signal must be DC-isolated from a power supply system and be accessible in the sense of these safety standards. An electric circuit of this type is referred to as an SELV or PELV electric circuit.

Circuit arrangements are known which satisfy this requirement by converting the analog signal, with an auxiliary energy being fed in, in such a way that the signal can be transmitted with the aid of simple optoelectronic elements, e.g. optocouplers and the DC isolation can thereby be achieved. This requires in some instances a relatively complicated conversion of the analog signal into a pulse-width-modulated square-wave signal, and vice versa, because simple optocouplers are only suitable for digital signals. Moreover, in a manner governed by the system, solutions of this type are not linear in the range around 0V or 10V input voltage. Although linear optocouplers with which an analog-to-digital conversion and vice versa is obviated are also known, they are expensive and generally have to be adjusted.

Another problem is also posed by different voltage ranges that are required for different assemblies or circuits. Whereas a 0 to 10 volt signal is industry standard e.g. for a desired value setting in a control loop, a microcontroller requires an input voltage range of e.g. 0 to 5 volts. This conversion has to be as free from errors as possible, i.e. the signal transmission has to be effected with the greatest possible linearity.

The invention is based on the object of providing a circuit arrangement of the type mentioned in the introduction which is highly linear and enables a DC signal isolation in a simple manner.

This object is achieved by virtue of the fact that the signal transformation part is designed as an inductive signal transformation part and the circuit arrangement is provided with a charging and discharging arrangement having a switching element in such a way that, as a result of the switching element being actuated, a charging or discharging current that is proportional to an input voltage and flows through the signal transformation part occurs and an output voltage is established at the voltage output.

It is advantageous if the inductive energy store contained in the signal transformation part is constructed with a core made of magnetizable material and a first (primary, number of turns n1) and second (secondary, number of turns n2) winding with the turns ratio ü=n1/n2.

The invention actually makes it possible to use an inductive signal transformation part, which is constructed e.g. like an AC transformer for the transmission of electrical energy, for the transmission of an arbitrary analog control signal (i.e. also of a DC voltage) in a simple manner without auxiliary energy being fed in on the input side.

Hitherto, transformers have been used e.g. for DC-isolated energy transmission with sinusoidal currents or other periodic alternating currents.

A further development thereof is clocked energy transmission systems such as e.g. switch-mode power supplies. The side effects that occur in this case are utilized by the invention described here.

Currents and voltages at the transformer are related here too by the turns ratio ü and can be measured at the primary and also at the secondary in the event of flux changes in the core. Thus, e.g. in the case of an inhibited primary current flow and a secondary-side demagnetization process, it is possible to measure a “mapping” of the secondary voltage at the primary winding.

In order to generate a magnetic flux in the core, the transformer in the signal transformation part is connected up to a switching element in such a way that the primary winding of the transformer is connected to voltage in the form of a temporally limited sampling, as a result of which a primary-side current flow can be generated. A magnetization of the core is thereby achieved. Immediately after the switching element is switched off, the primary-side current flow is interrupted, as a result of which the magnetization is terminated, which leads to a current flow (as conservation variable at the transformer) in the ratio ü in the secondary winding, which then brings about the demagnetization of the core. The driving variable for the demagnetization current is the output voltage of the transformer, which can be measured as a “reflected” mapping on the primary side of the transformer.

In order to realize the demagnetization current flow, a smoothing capacitor is preferably connected on the secondary side of the transformer, which smoothing capacitor is charged firstly by the control voltage fed in on this side and secondly by the energy transmitted via the transformer. A discharge resistor connected in parallel brings about a continuous discharging of the capacitor by the magnitude by which it was charged by the quantity of energy transmitted via the core per sampling process. This prevents a further and further rise in the voltage at the capacitor.

At the same time, a voltage divider connected upstream of the inductive signal transformation part is formed by an input-side resistor that forms a series circuit with the discharge resistor. Selection of identical resistors and a turns ratio of the transformer of ü=1 result in signal matching that reduces the 0-10 V input signal to the 0-5 V input of components connected downstream such as e.g. of a microcontroller. This matching must be effected as precisely as possible and as linearly as possible.

The invention's configuration of the circuit arrangement makes it possible to obviate not only at least one signal conversion circuit, e.g. for an analog-to-digital conversion and vice versa, but also a DC-isolated power supply for the conversion circuit.

The inductive signal transformation part is additionally independent of aging, cost-effective and requires little space, e.g. on a printed circuit board.

In comparison with optoelectronic solutions, the circuit arrangement according to the invention is highly linear and thus has a very low transmission error.

Further advantages of the invention are contained in the subclaims.

The invention and also further advantages thereof are explained in more detail with reference to an exemplary embodiment and the drawing. In this case, identical parts are always identified by the same reference symbols.

In the figures:

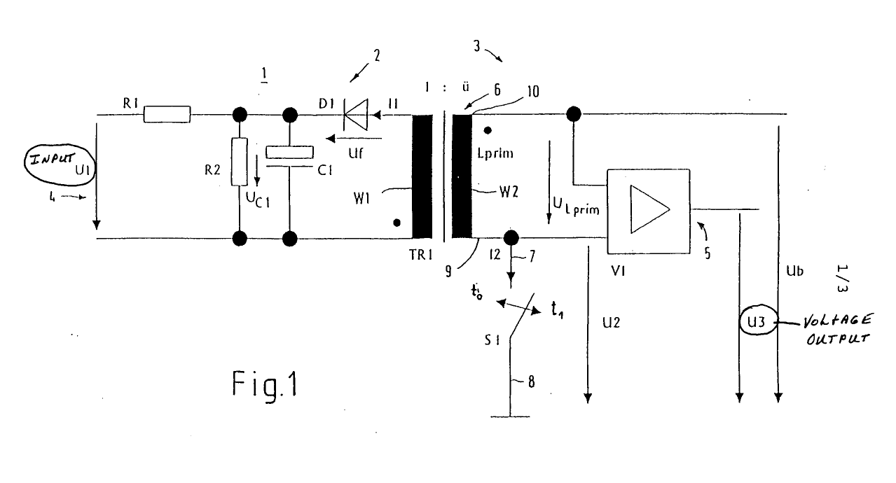

FIG. 1 shows a circuit arrangement according to the invention,

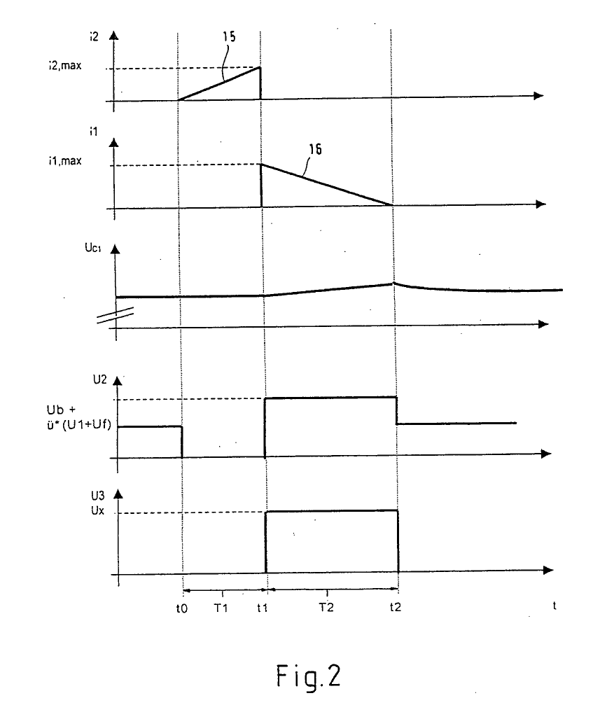

FIG. 2 shows current and voltage timing diagrams,

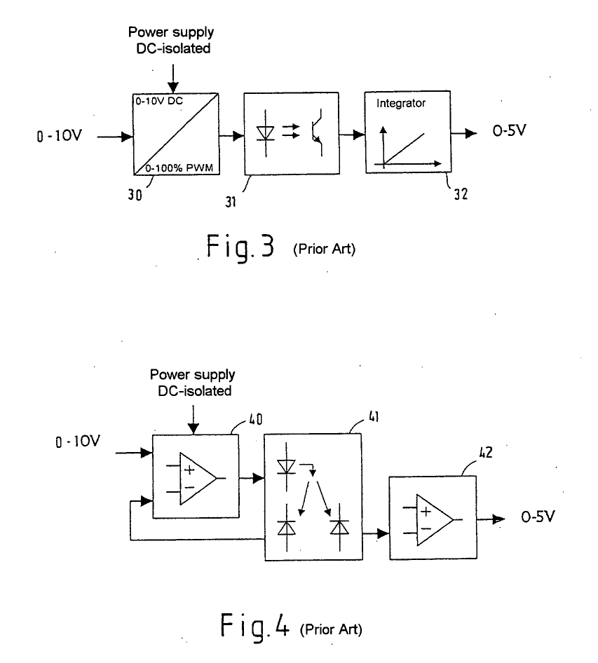

FIG. 3 shows, for comparison, a first known variant of a DC decoupling with a simple optocoupler, and

FIG. 4 shows, likewise for comparison, a second known variant of a DC decoupling with a linear optocoupler.

FIG. 1 shows an exemplary embodiment of a circuit arrangement 1 according to the invention. This circuit arrangement can be used in industry for controlling devices with an analog signal and with a voltage U1 of 0 to 10 volts. It may serve for example for desired value setting of a regulator or for evaluating a process variable in a control loop. In particular, it is used for rotational speed control of a commutatorless DC motor, a 0 to 10 volt input being present. An output-side voltage matching to 0 to 5 volts (U3) is additionally effected.

The circuit arrangement 1 has a voltage input 4 and a voltage output 5 and comprises two circuit parts 2 and 3 used to achieve a DC isolation, a linear transmission of an analog control variable and, in particular, the voltage matching between the voltage input U1 and the voltage output U3. The two circuit parts 2 and 3 are electrically connected to an inductive signal transformation part 6 such that a first winding W1 of the signal transformation part 6 is assigned to the input-side circuit part 2 and a second winding W2 of the signal transformation part 6 is assigned to the output-side circuit part 3.

The signal transformation part 6 is an inductive energy store and comprises, in a known manner, a closed core made of magnetizable material around which the two windings W1, W2 are arranged, the windings W1 and W2 running in opposite senses or the circuit parts 2, 3 being arranged in corresponding fashion as illustrated by the diagonally offset points at the windings W1, W2.

The input-side circuit part 2 preferably comprises two resistors R1, R2, a smoothing capacitor C1 and a diode D1. In this case, the smoothing capacitor C1 is electrically arranged between the electrical resistor R2 connected in parallel with it and the winding W1 or an inductance TR1 of the signal transformation part 6. Between the capacitor C1 and the winding W1, the diode acting as rectifying element D1 is connected up in the reverse direction with respect to the voltage input. Furthermore, a charging resistor R1 is connected upstream of the capacitor C1. The resistors R1 and R2 are connected in series and form a voltage divider. The charging resistor R1 is connected directly to the input, so that the input voltage U1 is divided in accordance with the division ratio between the two resistors R1, R2, said division ratio being defined by the resistors R1 and R2. The capacitor C1 is simultaneously a smoothing element and a charging and discharging element.

The output-side circuit part 3 preferably comprises a transistor as switching element S1 and a semiconductor element with differential inputs, which is embodied as a differential amplifier V1. The switching element S1 is connected to a winding end 9 of the signal transformation part 6 by one of its switching ends 7 and to ground or 0 volts by its other switching end 8. The differential amplifier V1 is connected up by its differential inputs to the two winding ends 9, 10 of the signal transformation part 6 that are on the control voltage output side. The output of the differential amplifier V1 forms the voltage output 5 with the output voltage U3.

The elements illustrated in FIG. 1 are connected according to the invention to form a charging and discharging arrangement which functions as follows:

The analog voltage U1 in the voltage range of 0 to 10 volts is present at the control voltage input 4. The capacitor C1 is charged to a voltage value Uc1, to be precise in accordance with the formula

$$Uc 1 = \frac{R 2}{R 1 + R 2} * U1 \qquad ( 1 )$$

In this case, the diode D1 prevents a current from flowing into the winding W1 on account of the voltage U1 since it is connected in such a way that it assumes a turned-off state during this charging operation. The resistors R1, R2 form a matching circuit part which can be used to alter an output voltage.

The switching element S1 enables a sampling operation. The value stored in the capacitor C1 is sampled in practice by the switching element S1, to be precise preferably from the DC-isolated side.

At the beginning of the sampling operation, the switching element S1 is closed at the instant t0, which is plotted on a time axis t in FIG. 2.

A current i2 that flows (primary) first through the second winding W2 and the switching element S1 rises until the switching element S1 switches off, to be precise according to the relationship:

$$\frac{ⅆ i 2}{ⅆ t} = \frac{Ub}{Lprim} \qquad ( 2 )$$

This ramped current rise of i2 is illustrated in FIG. 2, in the topmost curve (ramp 15).

Ub is in this case the voltage which is present across the inductance Lprim of the second winding W2 and is a fixed supply voltage of an output-side power supply (not illustrated).

At the instant ti, at which the switching element S1 opens again, a quantity of energy has been stored in the core of the signal transformation part 6, the signal transformation part 6 serving as an inductive energy store. Therefore, a specific quantity of energy is charged in practice into the signal transformation part 6 with the aid of the switching element S1.

This charged quantity of energy amounts to:

$$W = \frac{1}{2} * {Lprim ( I 2 , max )}^{2} \qquad ( 3 )$$

After the switching element S1 has opened, it is necessarily the case that a primary current i2 can no longer flow through the output-side winding W2 with the primary inductance Lprim, so that a secondary current i1 is established on the side of the winding W1, as is shown in the second diagram of FIG. 2. This effect is based on the fact that the current through the inductance is the conservation variable and is thus driven on by the inductance.

Instead of the current i2, then, the current i1 continues to flow in the secondary winding W2 until the instant t2, at which the core of the signal transformation part 6 is demagnetized and the secondary current i1 has decayed to the value zero.

The following relationship exists in this case:
I1, max=ü*I2, max (4)
where ü denotes the turns ratio between the two windings W1 and W2 and i1,max and i2,max denote the currents directly before and directly after the opening instant t1.

The ramped current fall (ramp 16) after the opening instant t1 amounts to:

$$\frac{ⅆ i 1}{ⅆ t} = - \frac{Uc 1 + Uf}{Lprim * {\ddot{u}}^{2}} \qquad ( 5 )$$

Uc1 is the voltage across the capacitor C1 and Uf is the voltage across the diode D1, which is connected in the forward direction for this current i1. Uf is constant, e.g. 0.7 volt, in a known manner.

The gradient of the second ramp 16 is dependent on the magnitude of the input voltage U1, as can be seen from equation (1) and equation (5). The voltage U1 in a time window is critical in this case. The time window T1 with a sampling beginning (t0) and a sampling end (t1) is necessary because signal sampling is involved, in principle, the sampled value (U3) being available after the instant t1 in a manner similar to that in the case of a sample & hold circuit (cf. FIG. 2). The voltage U1 need not be a constant DC voltage, but rather may also change, like any analog control signal. The sampling frequency with which the switching element is driven must be much higher in relation to the possible signal changes of the analog input signal. The sampling frequency may be e.g. 1 Hz to 100 kHz.

However, its value must principally be matched to the magnitude of C1 and R2 since the voltage Uc across the capacitor C1 rises by the amount ΔUc1 at the same time as the current fall of the current i1 (interval T2 between t1 and t2). By the next sampling that follows, the capacitor C1 must be discharged again by said amount via R2 since the voltage to be measured at the voltage output is otherwise corrupted. The third curve in FIG. 2 shows the voltage profile at C1.

ΔUc1 is calculated from:

$$Δ Uc 1 = \sqrt{\frac{Lprim * I 2 , {max}^{2}}{C 1}} \qquad ( 6 )$$

In this case, the voltage U2 across the opened switching element S1 is:
U2=ULprim+Ub (7)

As shown in FIG. 2, fourth curve, U2 is thus higher than Ub in this time interval T2.

ULprim is calculated from:

ULprim=ü*(U1+Uf+ΔUc1) (8)

It emerges from the abovementioned equations that:

$$U 2 = Ub + \ddot{u} * ( \frac{R 2}{R 1 + R 2} * U 1 + Uf + Δ Uc 1 ) \qquad ( 9 )$$

If the dimensioning of the inductance Lprim is small enough (or C1 is chosen to be large enough and R2 is chosen to have a sufficiently low resistance) that the voltage increase ΔUc1 is negligibly small compared with the voltage U1 (cf. equation 6), then the preceding equation 9 is simplified to:

$$U 2 = Ub + \ddot{u} * ( \frac{R 2}{R 1 + R 2} * U 1 + Uf ) \qquad ( 10 )$$

This is taken as a basis below.

Through the differential amplifier V1, the following results in the time interval T2 between t1 and t2:
U3=U2−Ub (11)

This results in the following:

$$U 3 = \ddot{u} * ( \frac{R 2}{R 1 + R 2} * U 1 + Uf ) \qquad ( 12 )$$

Given ü=1 and R1=R2, equation 12 is simplified to:

$$U 3 = \frac{1}{2} * U 1 + Uf \qquad ( 13 )$$

Half the input voltage U1 that is corrupted by the voltage Uf can thus be measured at the output 5 of the differential amplifier V1. However, since the voltage Uf is a fixed variable, the output voltage U3 can be corrected by the known voltage Uf, e.g. 0.7 volt, by suitable means or methods.

As is then apparent, the corrected DC-decoupled output voltage amounts to:

$$U 3 = \frac{1}{2} * U 1 \qquad ( 14 )$$

Consequently, a DC-isolated output voltage U3 of 0 to 5 volts, given an input voltage U1 of 0 to 10 volts, is present in time-discrete fashion by virtue of the circuit arrangement according to the invention.

FIG. 3 shows, for comparison, a first known variant of a DC decoupling with a simple optocoupler 31 (prior art). The input voltage must firstly be digitized by a PWM converter 30 because the optocoupler 31, comprising a transmitter and a receiver, can only transmit digital signals. An integrator 32 must put the signal into analog form again.

FIG. 4 shows, likewise for comparison, a second known variant of a DC decoupling with a linear optocoupler 41 with differential amplifiers 40 and 42 (prior art).

An additional DC-isolated power supply is required in both cases (FIG. 3, FIG. 4).

The invention is not restricted to the exemplary embodiments illustrated and described, but rather also encompasses all embodiments that are equivalent in the sense of the invention. Furthermore, the invention has also hitherto still not been restricted to the combination of features defined in claim 1, but rather may also be defined by any arbitrary other combination of specific features of all the individual features disclosed overall. This means that in principle practically any individual feature of claim 1 can be omitted or be replaced by at least one individual feature disclosed elsewhere in the application. In this respect, claim 1 is to be understood merely as a first attempt at formulation for an invention.

1. A circuit arrangement for DC-isolated transmission of an analog input variable, having a voltage input and a voltage output, and in particular for voltage matching between a voltage input and a voltage output of the circuit arrangement, the circuit arrangement comprising an inductive signal transformation part and the circuit arrangement is provided with a charging and discharging arrangement having a switching element, wherein as a result of the switching element being actuated, a charging or discharging current (i1, i2) that is proportional to an input voltage (U1) at the voltage input, and flows through the signal transformation part and an output voltage (U3) is established at the voltage output.

2. The circuit arrangement as claimed in claim 1 further comprising two circuit parts that are DC-isolated from the signal transformation part.

3. The circuit arrangement as claimed in claim 1 further comprising that the charging and discharging arrangement has an inductive energy store formed from the signal transformation part with a first and second winding and a core made of magnetizable material, the switching element being connected between the voltage output and the second winding of the signal transformation part in such a way that the switching element forms a sampling circuit part enabling a DC-isolated sampling of a voltage (Uc1).

4. The circuit arrangement as claimed in claim 3 in further comprising that the switching element is connected to a winding end of the signal transformation part by one of its switching ends and to ground or zero volts by its other switching end.

5. The circuit arrangement as claimed in claim 1 further comprising a differential amplifier is connected by its differential inputs to output-side winding ends of the signal transformation part, the output of the differential amplifier forming the voltage output with the output voltage (U3).

6. The circuit arrangement as claimed in claim 1 further comprising that the charging and discharging arrangement has a smoothing capacitor.

7. The circuit arrangement as claimed in claim 6 further comprising that the smoothing capacitor is electrically connected between a second electrical resistor connected in parallel with it and a winding on a winding side of the voltage input of the signal transformation part, a rectifying element being connected between the smoothing capacitor and the winding in such a way that it assumes a turned-off state in the case of a charging operation, and a first resistor being connected upstream of the smoothing capacitor.

8. The circuit arrangement as claimed in claim 6 further comprising that the switching element is connected up to an output-side winding side of the voltage output in such a way that the smoothing capacitor charged and discharged by the switching element being switched on and off, respectively.

9. The circuit arrangement as claimed in claim 6 further comprising that a sampling frequency achieved by repeated opening and closing of the switching element is dimensioned in such a way that, through discharging of the smoothing capacitor, a voltage increase occurring at the smoothing capacitor is possible by means of a second resistor.

10. The circuit arrangement as claimed in claim 1 further comprising a matching circuit part for matching the output voltage to the input voltage, which matching circuit part is connected between the voltage input and a first winding of the inductive signal transformation part.

11. The circuit arrangement as claimed in claim 10 further comprising that the matching circuit part has a series circuit comprising first and second electrical resistors that are connected to form a voltage divider.

12. The circuit arrangement as claimed in claim 11 wherein the voltage divider has a division ratio of approximately 1:2 and the inductive signal transformation part has a turns ratio (ü) of approximately ü=1.

13. The circuit arrangement as claimed in on the claim 10 further comprising that the circuit arrangement is adapted for the input signal to be in a voltage range of approximately 0 to 10 volts and on the output side for a voltage range of approximately 0 to 5 volts, a linear signal transmission being effected at least in these the ranges.

14. The circuit arrangement as claimed in claim 1 further comprising that the inductive signal transformation part has a primary winding and a secondary winding, which are wound around a closed magnetic core.

15. The circuit arrangement as claimed in claim 1 further comprising that the switching element is a semiconductor switching element.

16. A circuit arrangement as claimed in claim 1 used as a control unit.

17. A circuit arrangement as claimed in claim 1 used as a regulator.

18. The circuit arrangement as claimed in claim 17, wherein the regulator acts as a rotational speed regulator of an electric motor.

19. A method for the DC-isolated transmission of a voltage signal from an input side to an output side, characterized by an inductive sampling of a charged voltage signal (Uc1) from the DC-isolated output side.

20. The method as claimed in claim 19 further comprising a switch-on operation of a switching element, in the case of which a primary current (i2) through an output-side winding of an inductive signal transformation part rises in ramped fashion, and also a switch-off operation of the switching element, in the case of which the primary current (i2) falls to zero and then a secondary current flows in an input-side winding in a manner falling in ramped fashion.
